(19) United States
(12) Patent Application Publication
(10) Pub. No.: US 2016/0075550 A1
(43) Pub. Date: Mar. 17, 2016

(54) MEMS ELEMENT AND MANUFACTURING METHOD OF THE SAME

(71) Applicant: KABUSHIKI KAISHA TOSHIBA, Tokyo (JP)

(72) Inventors: Naofumi NAKAMURA, Tokyo (JP); Yumi HAYASHI, Zama Kanagawa (JP)

(73) Assignee: KABUSHIKI KAISHA TOSHIBA, Tokyo (JP)

(21) Appl. No.: 14/643,790

(22) Filed: Mar. 10, 2015

(30) Foreign Application Priority Data
Sep. 11, 2014 (JP) 2014-185120

(51) Int. Cl. B81B 7/00; B81C 1/00

(52) U.S. Cl. CPC B81B 7/0006; B81C 1/00301

(57) ABSTRACT

According to one embodiment, a MEMS element is disclosed. The element includes a substrate, a first electrode provided on the substrate, a second electrode disposed above the first electrode, a film including a connection hole defined by an inner wall communicating with the second electrode, the film and the substrate constituting a cavity in which the first electrode and the second electrode are contained. The element further includes an interconnect connected to the second electrode. The interconnect includes a portion arranged in the connection hole.

### CROSS-REFERENCE TO RELATED APPLICATIONS

This application is based upon and claims the benefit of priority from Japanese Patent Application No. 2014-185120, filed Sep. 11, 2014, the entire contents of which are incorporated herein by reference.

### FIELD

Embodiments described herein relate generally to a microelectromechanical system (MEMS) element and a manufacturing method of the same.

### BACKGROUND

A MEMS element comprises a substrate, a fixed electrode (lower electrode) formed on the substrate, and a movable electrode (upper electrode) formed above the fixed electrode. The MEMS element further comprises a diaphragm formed on the substrate. The diaphragm and the substrate form a cavity which accommodates the fixed electrode and the movable electrode. The diaphragm includes a first cap film having a plurality of through holes and a second cap film which closes the plurality of through holes.

### BRIEF DESCRIPTION OF THE DRAWINGS

FIG. 1A is a cross-sectional view illustrating a MEMS element of a first embodiment;

FIG. 1B is a plan view illustrating the MEMS element of the first embodiment;

FIG. 2 is a cross-sectional view for explanation of a method for manufacturing the MEMS element of the first embodiment;

FIG. 3 is a cross-sectional view for explanation of the method for manufacturing the MEMS element of the first embodiment, subsequently to FIG. 2;

FIG. 4 is a cross-sectional view for explanation of the method for manufacturing the MEMS element of the first embodiment, subsequently to FIG. 3;

FIG. 5 is a cross-sectional view for explanation of the method for manufacturing the MEMS element of the first embodiment, subsequently to FIG. 4;

FIG. 6 is a cross-sectional view for explanation of the method for manufacturing the MEMS element of the first embodiment, subsequently to FIG. 5;

FIG. 7 is a cross-sectional view for explanation of the method for manufacturing the MEMS element of the first embodiment, subsequently to FIG. 6;

FIG. 8A is a cross-sectional view for explanation of the method for manufacturing the MEMS element of the first embodiment, subsequently to FIG. 7;

FIG. 8B is a cross-sectional view showing another cross-sectional shape of a first cap film in the MEMS element of the first embodiment;

FIG. 8C is a plan view for explanation of the method for manufacturing the MEMS element of the first embodiment, subsequently to FIG. 7;

FIG. 9A is a cross-sectional view for explanation of the method for manufacturing the MEMS element of the first embodiment, subsequently to FIG. 8A;

FIG. 9B is a plan view for explanation of the method for manufacturing the MEMS element of the first embodiment, subsequently to FIG. 8C;

FIG. 10 is a cross-sectional view for explanation of the method for manufacturing the MEMS element of the first embodiment, subsequently to FIG. 9A;

FIG. 11 is a cross-sectional view for explanation of the method for manufacturing the MEMS element of the first embodiment, subsequently to FIG. 10;

FIG. 12A is a cross-sectional view illustrating a MEMS element of a second embodiment;

FIG. 12B is a plan view illustrating the MEMS element of the second embodiment;

FIG. 13 is a cross-sectional view illustrating a MEMS element of a third embodiment;

FIG. 14A is a cross-sectional view for explanation of a method for manufacturing the MEMS element of the third embodiment;

FIG. 14B is a plan view for explanation of the method for manufacturing the MEMS element of the third embodiment;

FIG. 15 is a cross-sectional view for explanation of the method for manufacturing the MEMS element of the third embodiment, subsequently to FIG. 14A;

FIG. 16 is a cross-sectional view for explanation of the method for manufacturing the MEMS element of the third embodiment, subsequently to FIG. 15;

FIG. 17 is a cross-sectional view for explanation of the method for manufacturing the MEMS element of the third embodiment, subsequently to FIG. 16;

FIG. 18 is a cross-sectional view for explanation of the method for manufacturing the MEMS element of the third embodiment, subsequently to FIG. 17;

FIG. 19A is a cross-sectional view illustrating a MEMS element of a comparative example in which a reference pressure is applied;

FIG. 19B is a cross-sectional view illustrating a MEMS element of the comparative example in which a pressure higher than a reference pressure is applied;

FIG. 19C is a plan view illustrating the MEMS element of the comparative example;

FIG. 20 is a plan view illustrating the MEMS element of another comparative example;

FIG. 21A is a cross-sectional view illustrating the MEMS element of another comparative example;

FIG. 21B is a plan view illustrating the MEMS element of another comparative example;

FIG. 22A is a cross-sectional view illustrating the MEMS element of yet another comparative example;

FIG. 22B is a plan view illustrating the MEMS element of yet another comparative example;

FIG. 23 is a plan view illustrating the MEMS element of yet another comparative example;

FIG. 24 is a plan view illustrating the MEMS element of another comparative example; and

FIG. 25 is a cross-sectional view showing an example of a structure in which a second cap film faces through holes and a connection hole.

### DETAILED DESCRIPTION

In general, according to one embodiment, a MEMS element is disclosed. The element includes a substrate; a first electrode provided on the substrate; a second electrode disposed above the first electrode; a film including a connection hole defined by an inner wall communicating with the second electrode, the film and the substrate constituting a cavity in which the first electrode and the second electrode are contained. The element further includes an interconnect connected to the second electrode. The interconnect includes a portion arranged in the connection hole.

In general, according to one embodiment, a method for manufacturing a MEMS element is disclosed. The method includes forming a first electrode on a substrate; forming a first sacrifice layer covering the first electrode on the substrate forming a second electrode on the first sacrifice layer; forming a second sacrifice layer covering the first sacrifice layer and the second electrode. The method further includes forming a connection hole in the second sacrifice layer, the connection hole communicating with the second electrode; forming a first film on the second sacrifice layer, the first film including a plurality of through holes communicating with the second sacrifice layer, and the first film covering a side surface of the connection hole to allow the second electrode to be exposed in the connection hole; forming an interconnect connected to the second electrode on the first film, the second electrode including a portion arranged in the connection hole. The method further includes forming a cavity by removing the first sacrifice layer and the second sacrifice layer through the plurality of through holes, the cavity being constituted by the substrate and the first film, and the first electrode and the second electrode being contained in the cavity; and forming a second film on the first film, the second film facing the plurality of through holes.

In general, according to one embodiment, a method for manufacturing a MEMS element is disclosed. The method includes forming a first electrode on a substrate; forming a first sacrifice layer covering the first electrode on the substrate; forming a second electrode on the first sacrifice layer; forming a second sacrifice layer covering the first sacrifice layer and the second electrode; forming a first connection hole in the second sacrifice layer, the first connection hole communicating with the second electrode. The method further includes forming a first film on the second sacrifice layer, the first film including a plurality of through holes communicating with the second sacrifice layer, and the first film covering a side surface of the first connection hole to allow the second electrode to be exposed in the connection hole; forming a cavity by removing the first sacrifice layer and the second sacrifice layer through the plurality of through holes, the cavity being constituted by the substrate and the first film, and the first electrode and the second electrode being contained in the cavity; forming a second film on the first film, the second film facing the first connection hole and the plurality of through holes. The method further includes forming a second connection hole in the second film by processing the second film on a bottom surface of the first connection hole, the second connection hole communicating with the second electrode; and forming an interconnect connected to the second electrode on the second film, the second electrode including a portion arranged in the second connection hole.

Embodiments will be hereinafter described with reference to the accompanying drawings. In the drawings, like or similar portions are denoted by the same reference numbers or symbols, and duplicated explanations are made as needed.

### First Embodiment

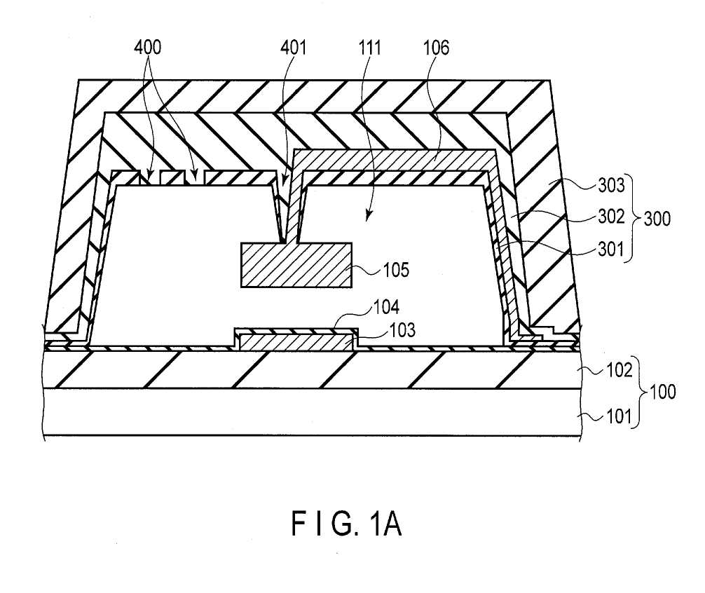

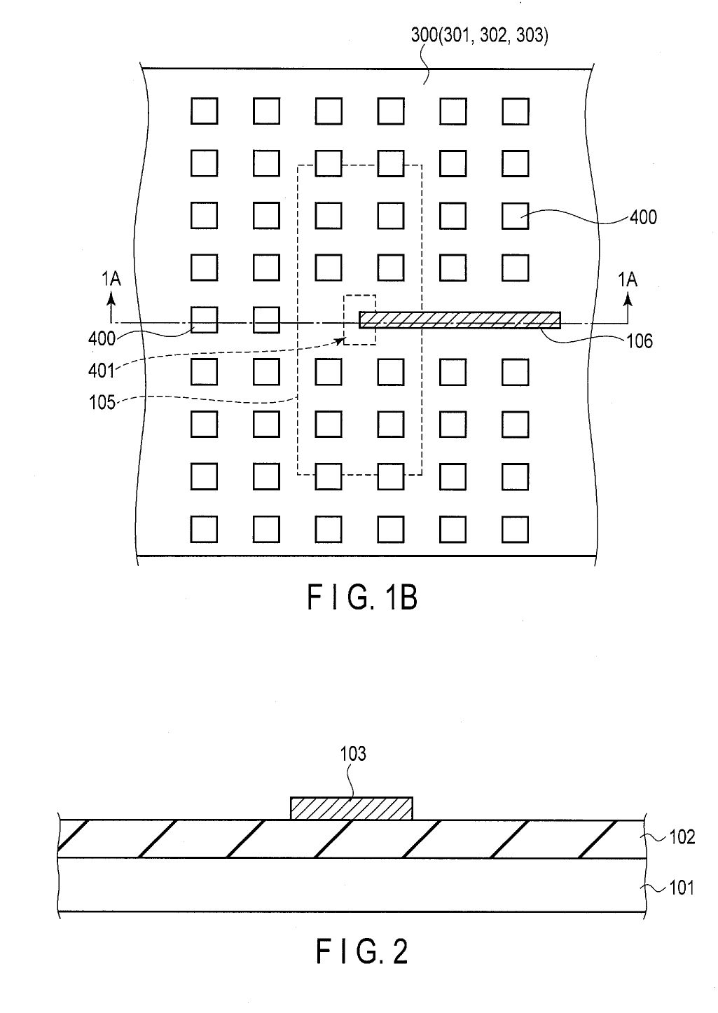

FIG. 1A and FIG. 1B are respectively a cross-sectional view and a plan view illustrating a MEMS element of the present embodiment. The cross-sectional view of FIG. 1A corresponds to section 1A-1A in the plan view of FIG. 1B.

The MEMS element of the present embodiment comprises a substrate 100, a fixed electrode (first electrode) 103 provided on the substrate 100, a movable electrode (second electrode) 105 provided over the fixed electrode 103, an interconnect 106 connected to an upper surface of the movable electrode 105, and a diaphragm (dome-shaped thin film) 300 which constitutes a cavity 111 accommodating the fixed electrode 103 and the movable electrode 105 together with the substrate 100.

The substrate 100 comprises a semiconductor substrate 101 and an insulating film 102 formed on the semiconductor substrate 101. The semiconductor substrate 101 is, for example, a silicon substrate. A semiconductor substrate such as an SOI substrate may be used instead of the silicon substrate. The insulating film 102 is, for example, a silicon oxide film.

The fixed electrode 103 is fixed on the substrate 100, and the movable electrode 105 is configured to move upwardly and downwardly in accordance with deformation of the diaphragm 300. The deformation of the diaphragm 300 occurs because of variation in external air pressure.

The diaphragm 300 includes a first cap film 301, a second cap film 302, and a third cap film 303. The second cap film 302 is formed on the first cap film 301, and the third cap film 303 is formed on the second cap film 302.

The first cap film 301 comprises a plurality of through holes 400. Each of the plurality of through holes 400 is defined by an inner wall facing the cavity 111. The plurality of through holes 400 are closed by the second cap film 302. The first cap film 301 further comprises a connection hole 401 defined by an inner wall communicating with the movable electrode 105. The connection hole 401 is, for example, arranged in the center of an upper surface of the first cap film 301 (dome-shaped thin film). In addition, the connection hole 401 is closed by the interconnect 106 and the second cap film 302.

Here, at least one cap film (hereinafter called a middle cap film; not shown) may be provided between the second cap film 302 and the third cap film 303. The middle cap film is formed, for example, in order to reinforce the diaphragm.

In addition, at least one cap film (hereinafter called an outer cap film; not shown) may be provided outside the third cap film 303. The outer cap film is formed, for example, in order to reinforce the diaphragm.

That is, the number of the cap films is not limited to three, but may be four or more.

FIG. 1A shows the structure in which the through holes 400 are closed by the second cap film 302, but the through holes 400 may be closed by the second cap film 302 and the third cap film 303.

The through holes 400 may also be closed by the second cap film 302 and the at least one middle cap film (not shown).

Furthermore, the through holes 400 may be closed by the second cap film 302, the at least one middle cap film and the third cap film 303.

The through holes 400 may also be closed by the second cap film 302, the at least one middle cap film, the third cap film 303 and the at least one outer cap film.

That is, when the at least one cap film including the second cap film 302 faces the through holes 400, the through holes 400 may be closed by the at least one cap film including the second cap film 302.

One of end portions of the interconnect 106 is arranged in the connection hole 401 and connected to the upper surface of the movable electrode 105. The other end portion of the interconnect 106 is connected to an interconnect (not shown) in the substrate 100. The other end portion of the interconnect 106 and the interconnect in the substrate 100 are connected by a via plug (not shown). In the drawing, 104 denotes a passivation film.

The MEMS element of the present embodiment will be further explained hereinafter according to its manufacturing method.

In the present embodiment, collective sealing (in-line wafer-level packaging [WLP]) of a plurality of MEMS elements on the wafer by thin film in a front-end process is described, but one MEMS element is hereinafter described for simple explanation. The MEMS element of the present embodiment is used for, for example, a pressure sensor.

[FIG. 2]

The insulating film 102 is formed on the semiconductor substrate 101. A conductive film to be processed into the fixed electrode 103 of the MEMS element is formed on the insulating film 102, thereafter, the fixed electrode 103 is formed by processing the conductive film by photolithography method and etching method.

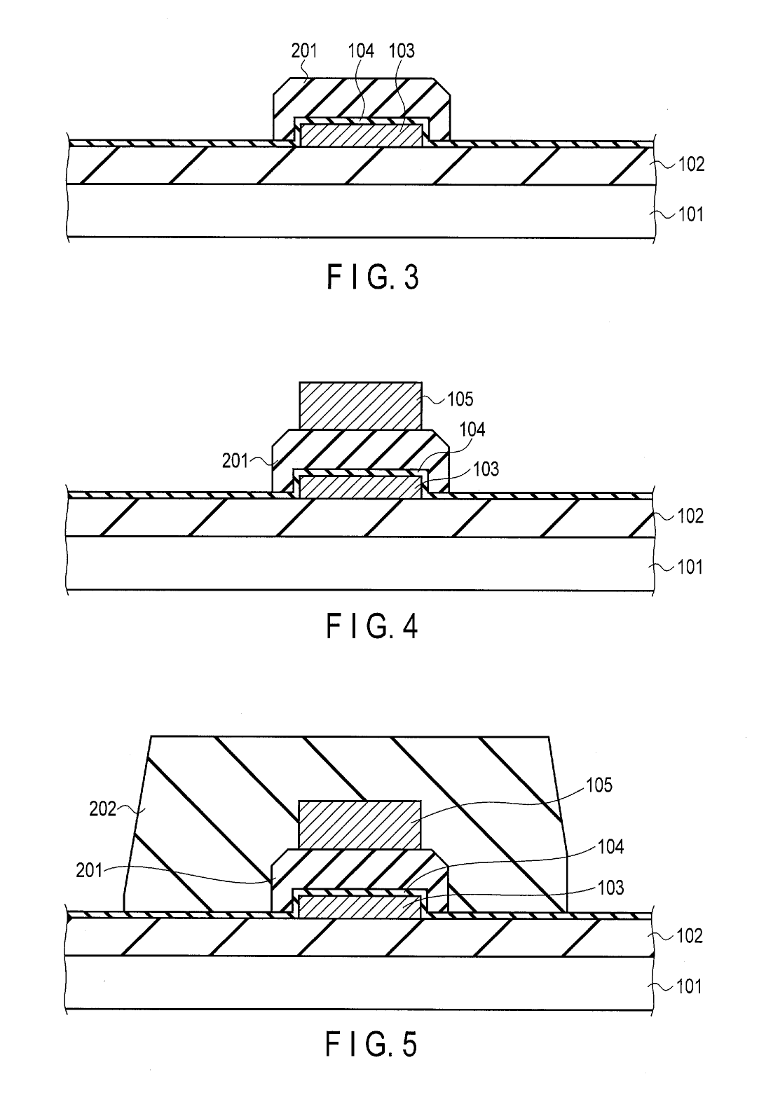

The etching method is, for example, reactive ion etching (RIE). Wet etching may be employed instead of RIE. The conductive film is, for example, an aluminum film. The aluminum film is formed by, for example, sputtering method. The fixed electrode 103 has a thickness ranging, for example, from several hundreds of nanometers to several micrometers.

[FIG. 3]

The passivation film 104 is formed on a region including the insulating film 102 and the fixed electrode 103. The passivation film 104 is formed by, for example, chemical vapor deposition (CVD) method. The passivation film 104 is, for example, an insulating film such as a silicon oxide film or a silicon nitride film. The passivation film 104 has a thickness ranging, for example, from several tens of nanometers to several micrometers.

A first sacrifice layer 201 in a predetermined shape is formed on the fixed electrode 103 and the passivation film 104. The fixed electrode 103 is covered with the first sacrifice layer 201 via the passivation film 104. The first sacrifice layer 201 is, for example, an insulating film formed of an organic substance such as polyimide. The sacrifice layer 201 has a thickness ranging, for example, from several hundreds of nanometers to several micrometers.

The sacrifice layer 201 is formed in, for example, three methods mentioned below.

In the first method, the insulating film (coating film) to be processed into the first sacrifice layer 201 is formed on an entire surface of the passivation film 104 by coating method such that coating film has a thickness ranging from several hundreds of nanometers to several micrometers, an unnecessary portion of the coating film is removed by exposure and development, and the first sacrifice layer 201 in a desired shape is formed.

In the second method, after the coating film is formed, a resist pattern is formed on the coating film by lithography method, the coating film is etched by RIE method using the resist pattern as a mask, and the first sacrifice layer 201 in a desired shape is formed.

In the third method, the coating film is formed, thereafter, a hard mask is formed on the coating film, the coating film is etched by RIE method or wet process using the hard mask as a mask, and the first sacrifice layer 201 in a desired shape is formed. A process of forming the hard mask comprises a step of forming the insulating film such as a silicon oxide film or a silicon nitride film on the coating film, a step of forming the resist pattern on the insulating film, and a step of etching the insulating film by RIE method using the resist pattern as a mask.

[FIG. 4]

The conductive film such as an aluminum film to be processed into the movable electrode (upper electrode) 105 is formed on a region including the passivation film 104 and the first sacrifice layer 201, thereafter the movable electrode 105 is formed on the first sacrifice layer 201 by processing the conductive film. The processing of the conductive film is performed by, for example, photolithography method and RIE method. Wet etching may be employed instead of RIE method. The movable electrode 105 has a thickness ranging, for example, from several hundreds of nanometers to several micrometers.

[FIG. 5]

Subsequently, the step of wafer level packaging (WLP) is performed.

A second sacrifice layer 202 in a predetermined shape is formed on a region including the fixed electrode 103, the passivation film 104, the first sacrifice layer 201 and the movable electrode 105. The first sacrifice layer 201 and the movable electrode 105 are covered with the second sacrifice layer 202.

An upper surface of the second sacrifice layer 202 is, for example, plane. The second sacrifice layer 202 in such a shape can be obtained by, for example, forming a film (coating film) made of an organic substance such as polyimide to have a thickness ranging from several hundreds of nanometers to several micrometers by a coating method, and by patterning to the coating film.

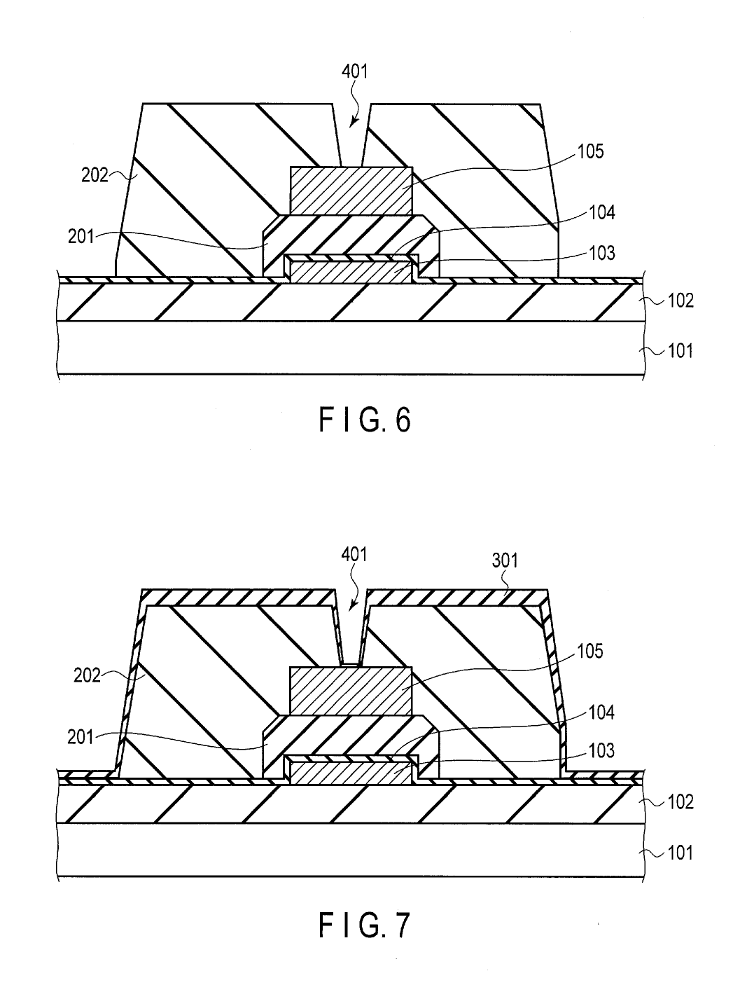

The Examples of patterning method for the coating film include comprising steps of coating the second sacrifice layer 202 and removing an unnecessary portion of the second sacrifice layer 202 by exposure and development, or a method comprising steps of forming the resist pattern on the second sacrifice layer 202 by lithography method and etching the second sacrifice layer 202 by RIE method using the resist pattern as a mask to remove an unnecessary portion of the second sacrifice layer 202, or a method comprising steps of forming the hard mask on the second sacrifice layer 202 and etching the second sacrifice layer 202 by RIE method or wet process using the hard mask as a mask to remove an unnecessary portion of the second sacrifice layer 202.

[FIG. 6]

The connection hole 401 communicating with the upper surface of the movable electrode 105 is formed in the second sacrifice layer 202 by photolithography method and etching method. The connection hole 401 is formed in the first cap film 301. For simple explanation, a through hole communicating with the upper surface of the movable electrode 105 formed in the second sacrifice layer 202 is also called a connection hole 401. When the upper surface of the second sacrifice layer 202 is plane, the photolithography method to form the connection hole 401 can be performed easily.

[FIG. 7]

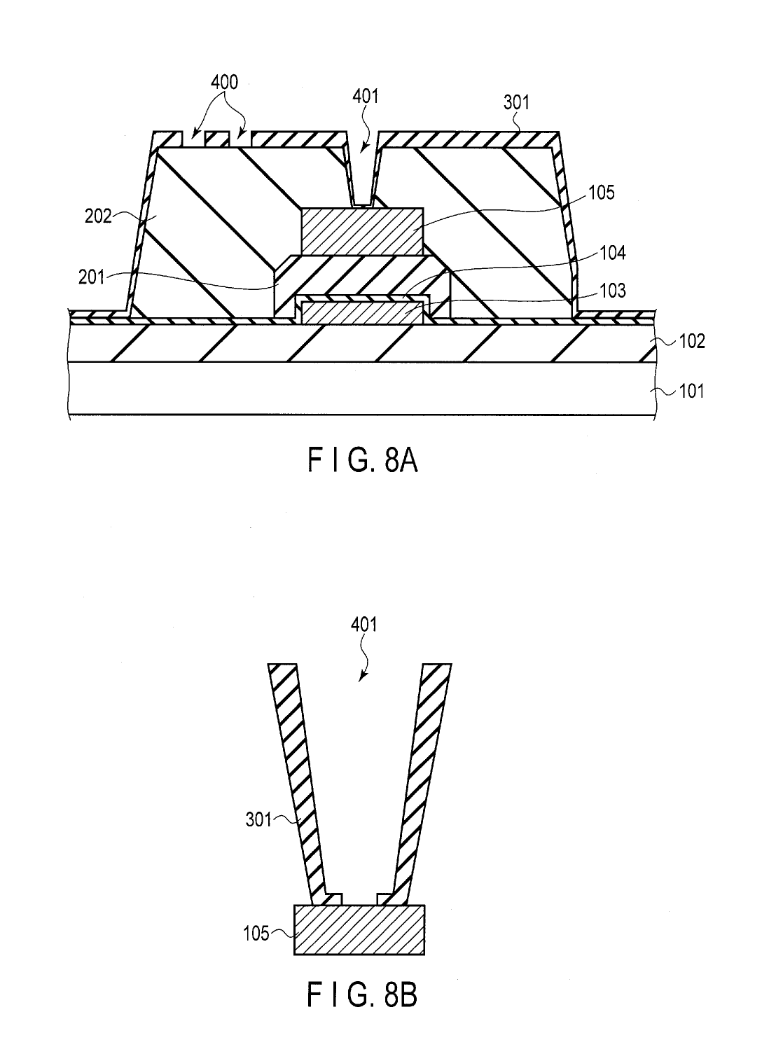

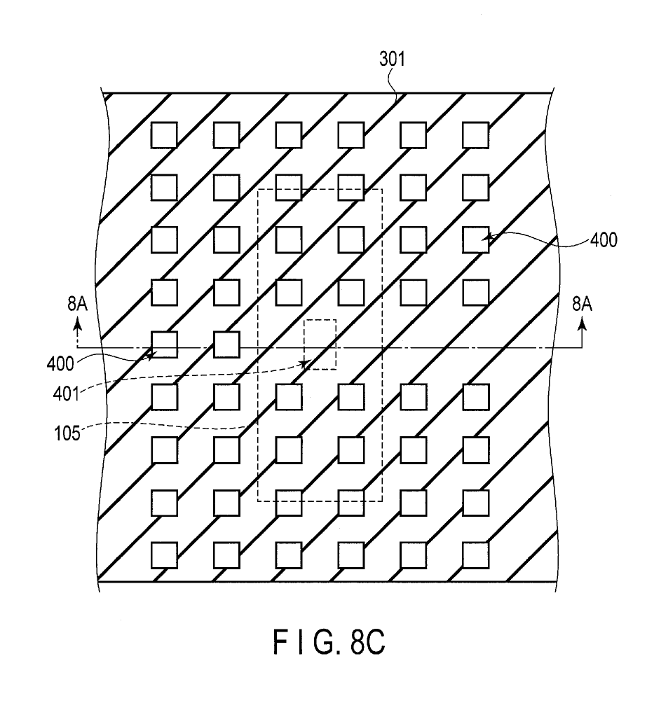

The first cap film 301 is formed on the entire surface (i.e., exposed surfaces of the passivation film 104, the movable electrode 105 and the second sacrifice layer 202) so as to cover the inner surface of the connection hole 401.

[FIG. 8A, FIG. 8B, FIG. 8C]

The through holes 400 and the connection hole 401 are formed in the first cap film 301 by processing the first cap film 301 by, for example, photolithography method and etching method. The etching method is the RIE method or wet etching method. The cross-sectional view of FIG. 8A corresponds to section 8A-8A in the plan view of FIG. 8C. The connection hole 401 having the cross section shown in FIG. 8A may not be formed, but the first cap film 301 having a lateral cross section shaped in a protrusion on the bottom surface of the connection hole 401 as shown in FIG. 8B may be formed.

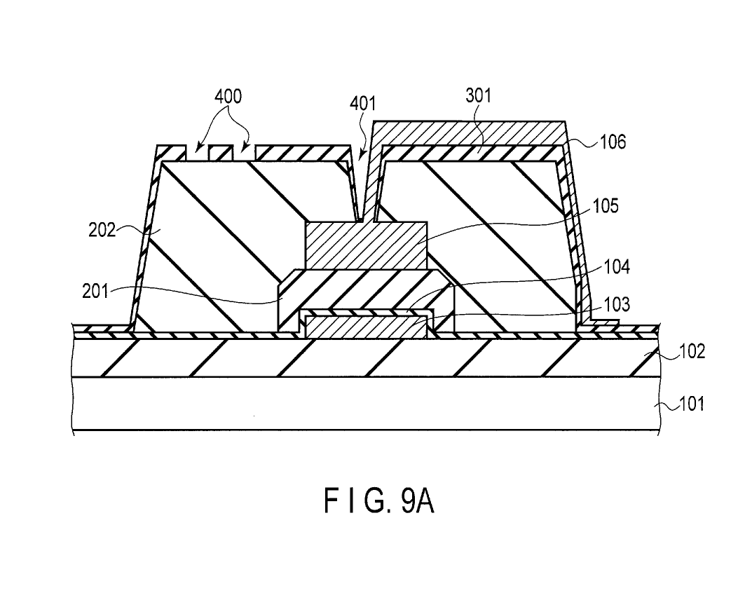

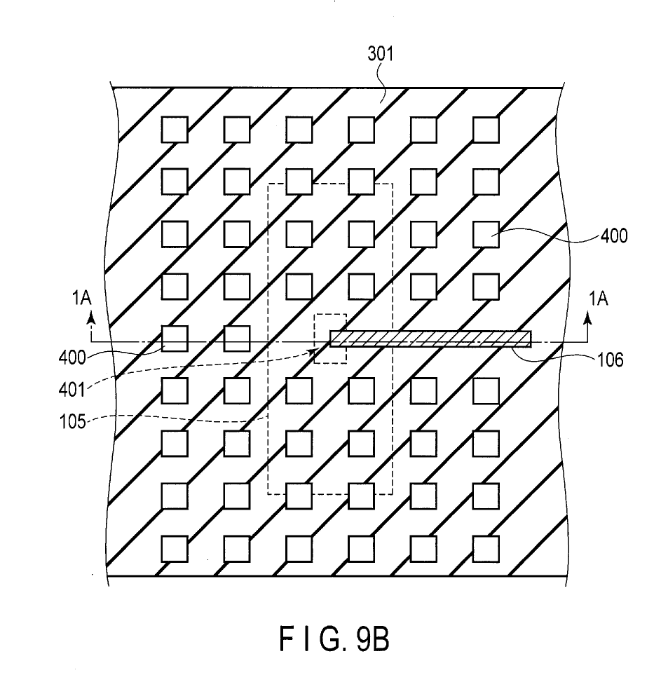

In the present embodiment, the through holes 400 are formed on the upper surface (ceiling) of the first cap film 301. However, the through holes 400 are not formed in a region of the upper surface of the first cap film 301 where an interconnect 106 (FIG. 9B) to be explained later is formed.

The through holes 400 are used to supply gas to remove the first sacrifice layer 201 and the second sacrifice layer 202 into the first cap film 301.

The first cap film 301 is an inorganic film (for example, a silicon oxide film) having a thickness ranging from several hundreds of nanometers to several micrometers. The first cap film 301 is formed by, for example, CVD. In the present embodiment, an insulating cap film is thus used as the first cap film 301. This is because an insulating cap film is generally greater than a conductive cap film with respect to the degree of deformation relative to pressure variation and the sensitivity can be made higher by using an insulating cap film. For the same reason, insulating cap films are used as the second cap film 302 and the third cap film 303, in the present embodiment. The at least one middle cap film (not shown) and the at least one outer cap film (not shown) are, for example, inorganic films such as silicon oxide films.

The through holes 400 can be obtained by, for example, forming a resist pattern (not shown)having a plurality of through holes on the inorganic thin film and processing the inorganic thin film by RIE method or wet etching method using the resist pattern as a mask.

[FIG. 9A, FIG. 9B]

The interconnect 106 connected to the movable electrode 105 is formed on the first cap film 301. The material of the interconnect 106 is, for example, aluminum. The plane pattern of the interconnect 106 is, for example, linear as shown in FIG. 9B. One of end portions of the interconnect 106 is arranged in the connection hole 401 and connected to the upper surface of the movable electrode 105. The other end portion of the interconnect 106 is arranged on a plane region of the first cap film 301 outside the second sacrifice layer 202.

A process for forming the interconnect 106 comprises, for example, a step of forming a conductive film such as an aluminum film on the first cap film 301 so as to cover the inner surface of the connection hole 401 and a step of processing the conductive film by photolithography method and etching method.

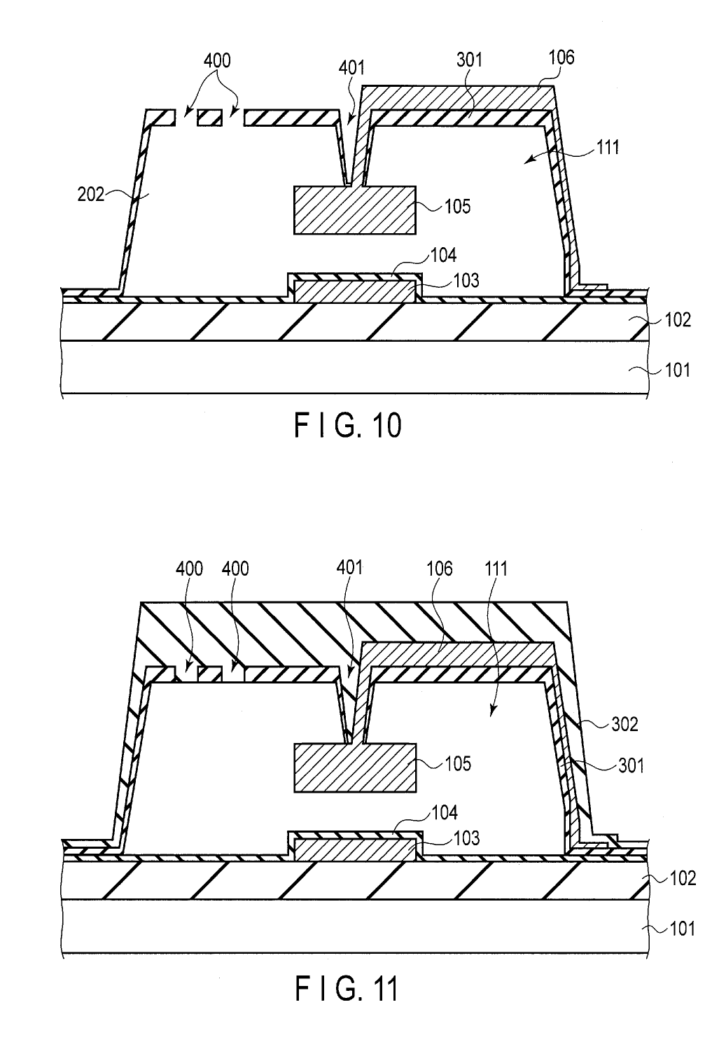

The through holes 400 are not formed on the upper surface of the first cap film 301 in the region (interconnect formation region) where the interconnect 106 is formed. The through holes 400 are used to supply gas into the first cap film 301 as explained above. If the interconnect 106 is formed on the through hole 400, some or all portions of the through hole 400 are closed by the interconnect 106. Such a through hole 400 is not suitable for supply of the gas into the first cap film 301.

[FIG. 10]

Gas for removal of the first sacrifice layer 201 and the second sacrifice layer 202, for example, gaseous oxygen (O₂) is supplied into the first cap film 301 (ashing), through the through holes 400, and the first sacrifice layer 201 and the second sacrifice layer 202 are thereby removed. Thus, the cavity 111 which is an operation space of the MEMS element is formed by the substrate 100 and the first cap film 110.

[FIG. 11]

The second cap film 302 is formed in a region including the first cap film 301 and the interconnect 106 by a coating method.

In the present embodiment, the second cap film 302 is an organic film (insulating film) containing an organic substance such as polyimide-based resin as the material. In this case, the second cap film 302 can be formed to fill the through holes 400 and the connection hole 401. Permeability of harmful gas, for example, vaporized moisture and moisture gas, of the second cap film 302 becomes higher than that of the first cap film 301 (inorganic film such as a silicon oxide film).

If a film having a higher permeability of harmful gas than that of the first cap film 301 is used as the second cap film 302, the harmful gas (for example, vaporized moisture) in the cavity 111 is exhausted through the second cap film 302 and an interior of the cavity 111 can be maintained in preferable atmosphere in a period from the formation of the second cap film 302 to the formation of the third cap film 303.

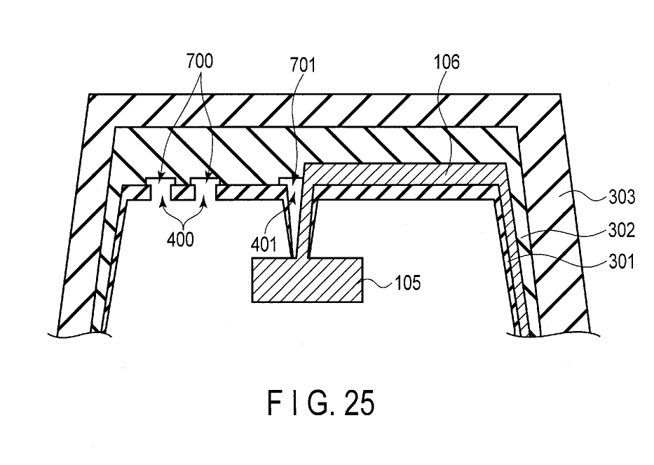

The second cap film 302 may not fill the through holes 400 or the connection hole 401, but may close the through holes 400 or the connection hole 401. In addition, the second cap film 302 may not close the through holes 400 or the connection hole 401, but may face the through holes 400 or the connection hole 401. FIG. 25 is a cross-sectional view showing an example of a structure in which the second cap film 302 faces the through holes 400 or the connection hole 401. Spaces (gaps) 700 exist between the second cap film 302 and the through holes 400 and, similarly, a space (gap) 701 exists between the second cap film 302 and the connection hole 401.

The second cap film 302 and the third cap film 303 may not fill the through holes 400 or the connection hole 401, but may close or face the through holes 400 or the connection hole 401.

In addition, the second cap film 302 and at least one middle cap film (not shown) may not fill the through holes 400 and the connection hole 401, but may close or face the through holes 400 and the connection hole 401.

Furthermore, the second cap film 302, at least one middle cap film and the third cap film 303 may not fill the through holes 400 and the connection hole 401, but may close or face the through holes 400 and the connection hole 401.

Moreover, the second cap film 302, at least one middle cap film, the third cap film 303 and at least one outer cap film may not fill the through holes 400 and the connection hole 401, but may close or face the through holes 400 and the connection hole 401.

That is, at least one cap film including the second cap film 302 may face, close or fill the through holes 400 and the connection hole 401.

After that, the third cap film 303 is formed on the second cap film 302, and the WLP diaphragm (first to third cap films 301, 302, 303) is completed, as shown in FIG. 1A. The MEMS element shown in FIG. 1A can be thus obtained.

The third cap film 303 plays a role of a moisture prevention film. To play the role, the third cap film 303 may preferably have a lower permeability of harmful gas than the second cap film 302. Such a relationship in permeability can be implemented by, for example, forming the third cap film 303 as a deposition film by CVD and forming the second cap film 302 as a coating film by spin coating.

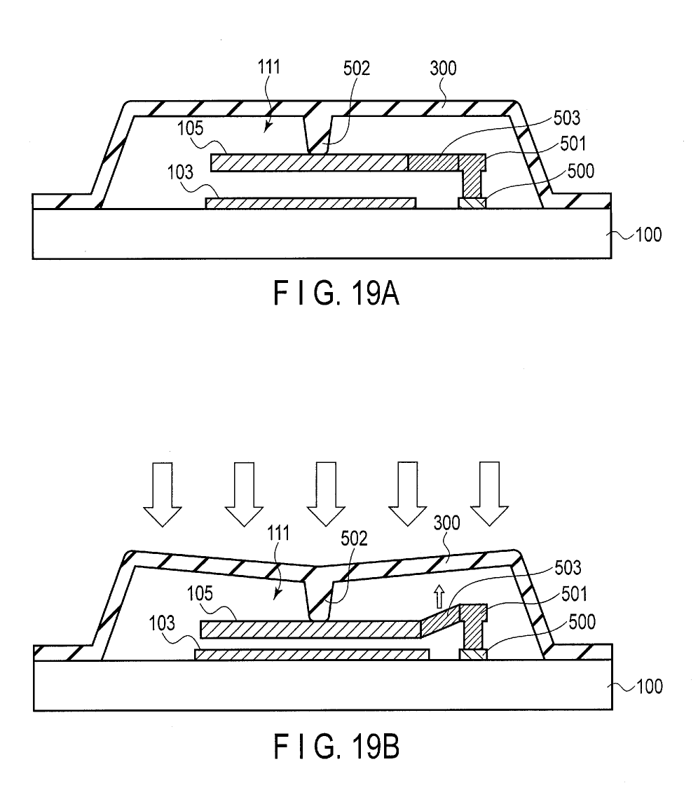

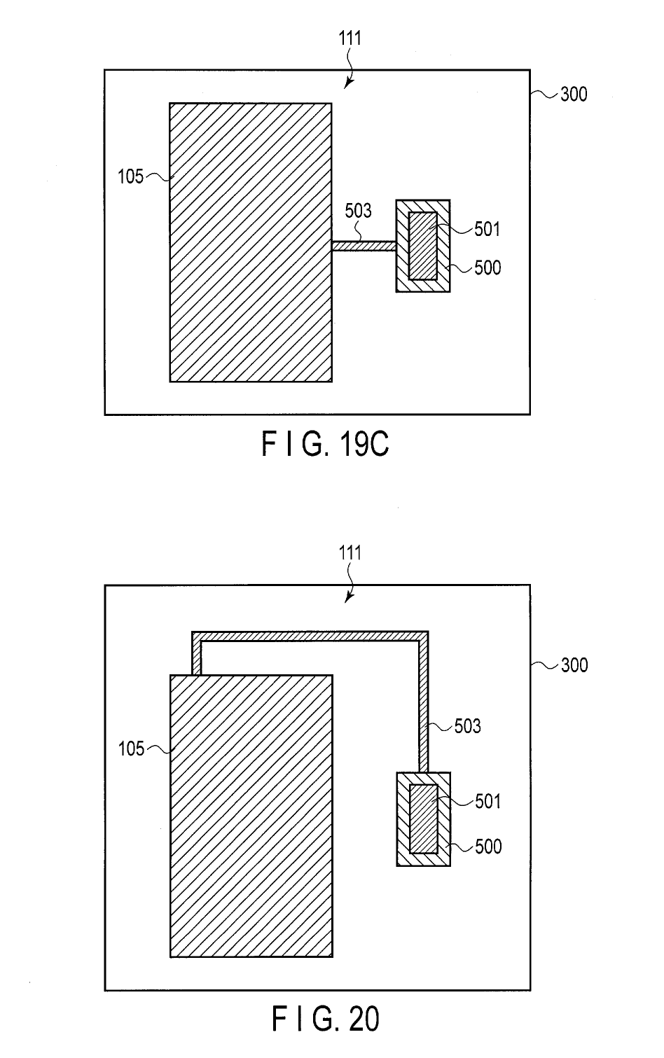

FIG. 19A is a cross-sectional view illustrating a MEMS element of a comparative example in a state in which pressure is not applied to the diaphragm 300, FIG. 19B is a cross-sectional view illustrating a MEMS element of a comparative example in a state in which pressure 600 is applied to the diaphragm 300, and FIG. 19C is a plan view illustrating a MEMS element of a comparative example.

FIG. 19A is a cross-sectional view illustrating a MEMS element of a comparative example in a state in which a reference pressure (for example, 1 atm pressure) is applied to the diaphragm 300, and FIG. 19B is a cross-sectional view illustrating a MEMS element of a comparative example in a state in which the pressure 600 higher than the reference pressure is applied to the diaphragm 300.

In FIG. 19A to FIG. 19C, 500 denotes an interconnect, and the interconnect 500 corresponds to the interconnect 106 of the present embodiment. A first anchor portion 501 is provided on the interconnect 500. A second anchor portion 502 is provided on an upper surface of the movable electrode 105. A material of the second anchor portion 502 is an insulator. The movable electrode 105 is connected to the diaphragm 300 via the second anchor portion 502. In addition, the movable electrode 105 is connected to the interconnect 500 via a spring portion 503 and the first anchor portion 501. A plane pattern of the spring portion 503 is, for example, linear as shown in FIG. 19C.

In the comparative example, the spring portion 503 is provided inside the cavity 111 and a material of the spring portion 503 is a conductor. For this reason, the spring portion 503 influences a capacitance between the fixed electrode 103 and the movable electrode 105.

In contrast, in the present embodiment, the influence on the capacitance can be greatly reduced since a member corresponding to the spring portion 503 does not exist in the cavity 111.

In the comparative example, as shown in FIG. 19B, an upward force 601 is applied to the spring portion 503 when the pressure 600 which forces the movable electrode 105 to move downwardly is applied to the diaphragm 300. An upward force is also applied to an end portion of the movable electrode 105 on the spring portion 503 side because of the influence of the force 601 on the spring portion 503. As a result, a distance between the movable electrode 105 and the fixed electrode 103 can easily become greater than a predetermined value, on the spring portion 503 side. This may cause degradation of characteristics such as sensitivity (pressure dependency of the capacitance) to occur in the MEMS element.

To reduce the force on the end portion of the movable electrode 105 due to the influence of the force 601 on the spring portion 503, a spring modulus of the spring portion 503 needs to be reduced. To reduce the spring modulus of the spring portion 503, for example, the spring portion 503 may be elongated. The elongated spring portion 503 can be implemented by, for example, arranging the spring portion 503 in a bent shape within the cavity 111 as shown in a plane view of FIG. 20.

The MEMS element comprising the bent spring portion 503 shown in FIG. 20 is unsuitable for miniaturization since, in this MEMS element, space required for the spring portion 503 becomes large and the size of the diaphragm 300 needs to be great as compared with the MEMS element comprising the linear spring portion 503 shown in FIG. 19C. In addition, the bent spring portion 503 may be deformed due to influence of heat in a process performed after formation of the spring portion, for example, a process of removing a sacrifice layer or a process of forming a third cap film (not shown) forming the diaphragm 300.

In contrast, in the present embodiment, upward force is not applied to the end portion of the movable electrode 105 even if the pressure forcing the movable electrode 105 to move downwardly is applied to the diaphragm 300, since a member such as the spring portion 503 is not connected to the end portion of the movable electrode 105. Degradation of characteristics such as sensitivity (pressure dependency of the capacitance) is thereby suppressed.

In addition, since the planar pattern of the interconnect 106 is linear as shown in FIG. 9B, i.e., is not bent, the size of the first cap film 301 does not need to be larger. For this reason, the interconnect 106 is not an obstacle to miniaturization of the MEMS element.

### Second Embodiment

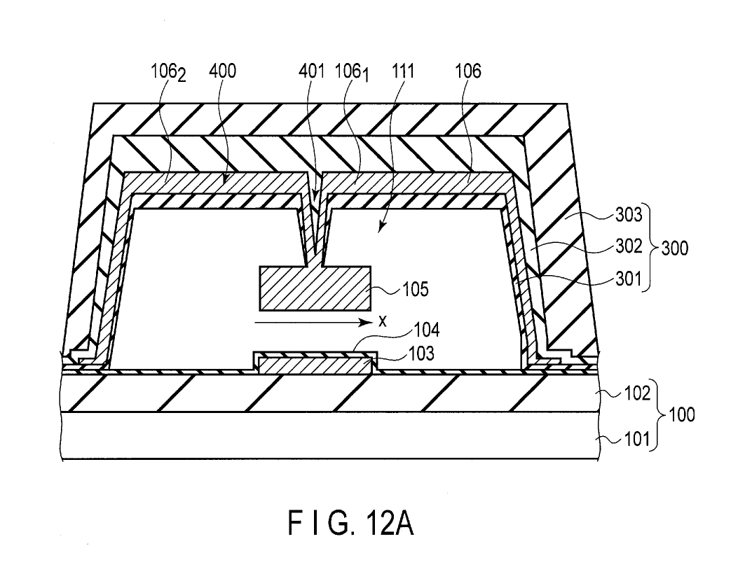

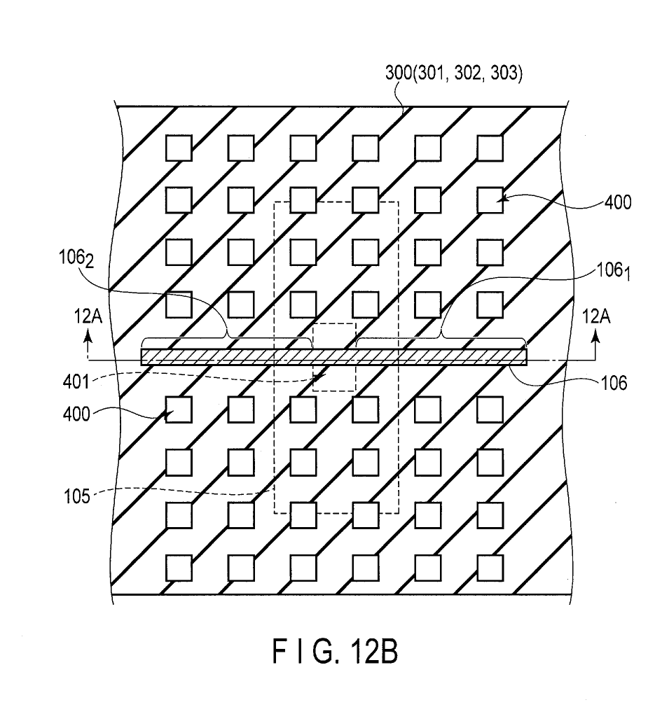

FIG. 12A and FIG. 12B are a cross-sectional view and a plan view each illustrating the MEMS element of the present embodiment. The cross-sectional view of FIG. 12A corresponds to section 12A-12A in the plan view of FIG. 12B.

In the present embodiment, a plane pattern of an interconnect 106 includes, outside a connection hole 401, a first region 106₁ extending along a first direction and a second region 106₂ extending along a direction opposite to the first direction (i.e., a direction of −180° from the first direction) from the connection hole 401, as shown in FIG. 12B.

The first region 106₁ and the second region 106₂ are connected to each other by the interconnect 106 in the connection hole 401. An end portion of the second region 106₂ is connected to, for example, a dummy interconnect (not shown) in a substrate 100 through a via plug (not shown). Alternately, the end portion of the second region 106₂ may be connected to an interconnect (not shown) in the substrate 100, similarly to an end portion of the first region 106₁.

The movable electrode 105 of the present embodiment is also supported by the interconnect 106 in the connection hole 401, the interconnect 106 of a portion corresponding to the first region 106₁, and the interconnect 106 of a portion corresponding to the second region 106₂. The interconnect 106 of the portion corresponding to the first region 106₁ and the interconnect 106 of the portion corresponding to the second region 106₂ are arranged at positions symmetrical with respect to the connection hole 401.

For this reason, for example, variation in a distance between the movable electrode 105 and the fixed electrode 103 across an x axis (i.e., an axis parallel to the first region 106₁ and the second region 106₂) of FIG. 12A can be made smaller as compared with supporting the movable electrode 105 by the interconnect 106 in the connection hole 401 and the interconnect 106 of the portion corresponding to the first region 106₁.

In the present embodiment, the interconnect 106 comprises the regions 106₁ and 106₂ extending along two different directions, but the interconnect 106 may comprise regions extending along three or more different directions.

To manufacture the MEMS element of the present embodiment, for example, a conductive film to be processed into the interconnect 106 is processed to be in a shape of the interconnect 106 of the present embodiment by photolithography method and etching method, in the steps shown in FIG. 9A and FIG. 9B of the first embodiment. In this case, through holes 400 are not formed on a first cap film 301 under the second region 106₂.

### Third Embodiment

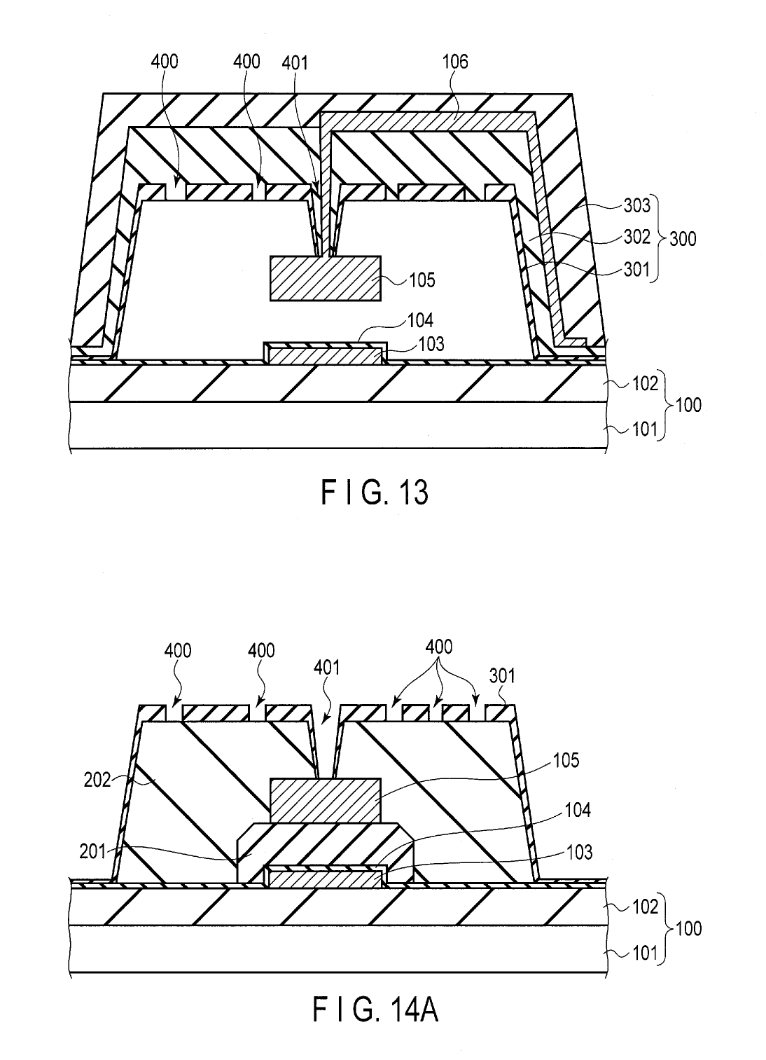

FIG. 13 is a cross-sectional view illustrating a MEMS element of the present embodiment.

The present embodiment is different from the first embodiment with respect to a point that an interconnect 106 is provided on a second cap film 302.

The second cap film 302 comprises no through holes through which gas is supplied. For this reason, the interconnect 106 can be designed without considering a position or dimensions of the through hole, and a degree of freedom of the interconnect 106 on the second cap film 302 is increased.

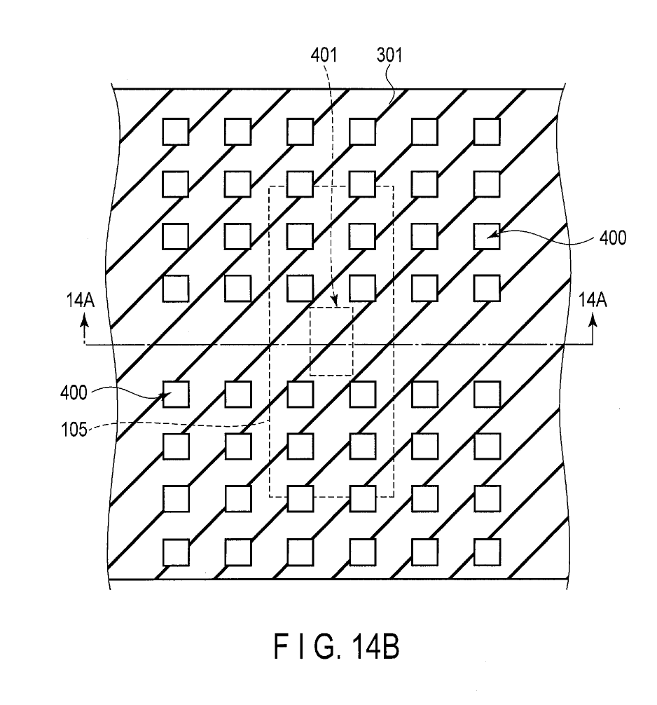

An example of a method of manufacturing the MEMS element of the present embodiment will be hereinafter explained.

[FIG. 14A, FIG. 14B]

After the step of the first embodiment shown in FIG. 7, through holes 400 and a connection hole (first connection hole) 401 in a first cap film 301.

The first cap film 301 comprise a plurality of through holes 400 as shown in a plan view of FIG. 14B. The cross-sectional view of FIG. 14A corresponds to section 14A-14A in the plan view of FIG. 14B.

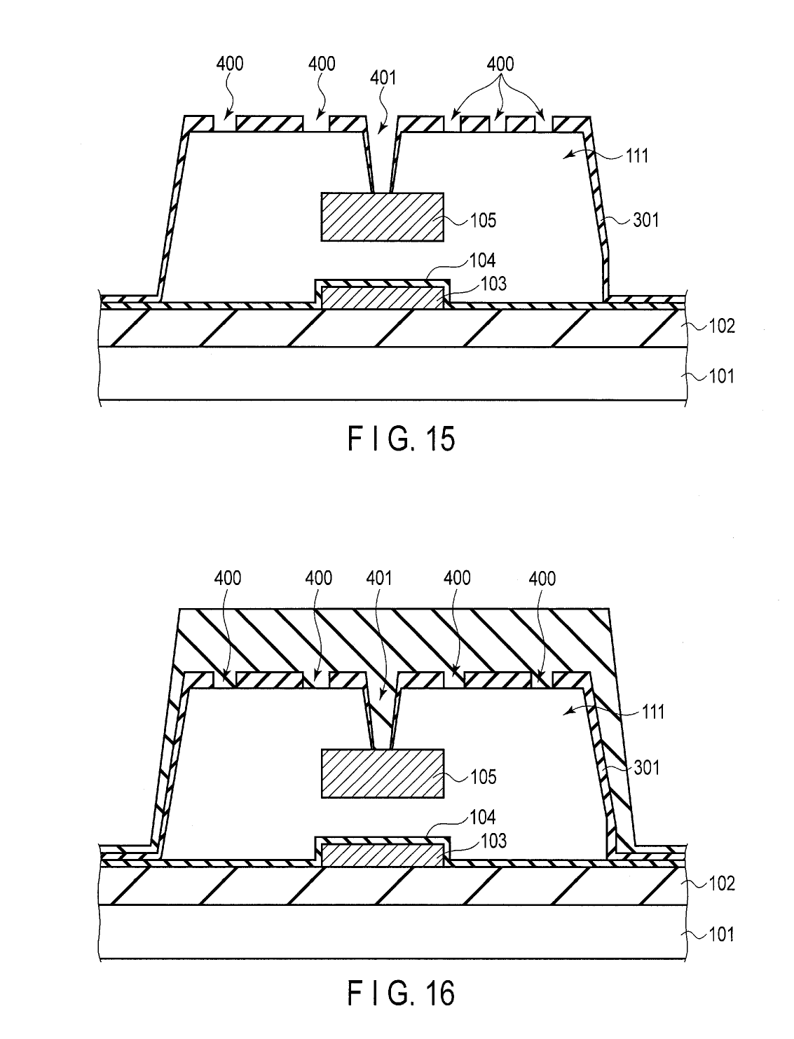

In the present embodiment, the through holes 400 are also formed in a region of the upper surface of the first cap film 301 corresponding to the region where the interconnect 106 is formed in the first embodiment, since the interconnect 106 is not formed on the upper surface of the first cap film 301. The number of the through holes 400 formed in the first cap film 301 of the present embodiment is therefore greater than the number of the through holes 400 formed in the first cap film 301 of the first embodiment.

[FIG. 15]

By supplying gas for removal of a first sacrifice layer 201 and a second sacrifice layer 202 into the first cap film 301 through the through holes 400, the first sacrifice layer 201 and the second sacrifice layer 202 are removed and a cavity 111 is formed.

Since the number of the through holes 400 in the present embodiment is greater than the number of the through holes 400 in the first embodiment as explained above, the gas can be efficiently supplied into the first cap film 301. The first sacrifice layer 201 and the second sacrifice layer 202 can be thereby removed more efficiently.

[FIG. 16]

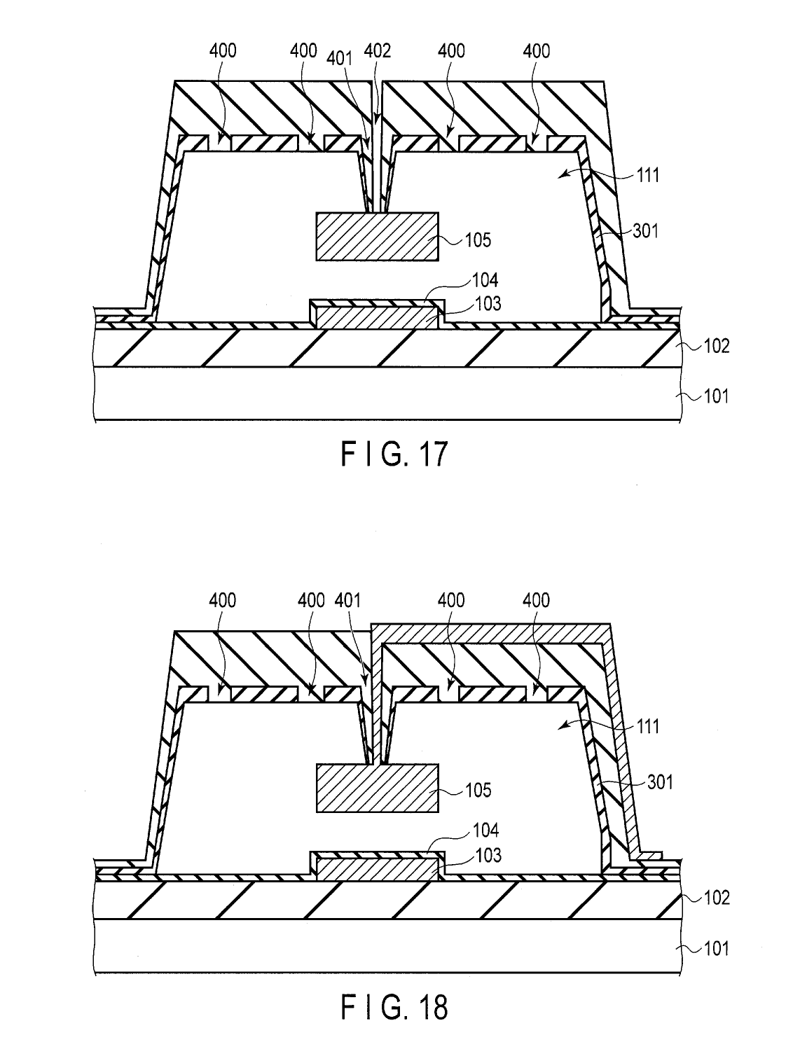

A second cap film 302 is formed on the first cap film 301. The second cap film 302 is formed to fill or close the through holes 400 or the connection hole 401. FIG. 16 shows the second cap film 302 which fills the through holes 400 or the connection hole 401.

[FIG. 17]

By processing the second cap film 302 on a bottom surface of the connection hole 401 by, for example, photolithography method and etching method, a connection hole (second connection hole) 402 which communicates with an upper surface of the movable electrode 105 is formed in the second cap film 302. The etching method is RIE method or wet etching method.

[FIG. 18]

The interconnect 106 connected to the upper surface of the movable electrode 105 is formed on the second cap film 302. In the present embodiment, the second connection hole 402 is filled by the interconnect 106. One of end portions of the interconnect 106 is arranged in the connection hole 402 and connected to the upper surface of the movable electrode 105.

A third cap film 303 is formed on the second cap film 302, and the MEMS element shown in FIG. 15 is thereby obtained. If the second connection hole 402 includes a region (cavity) which is not filled by the interconnect 106, the cavity is filled by the third cap film 303.

The interconnect 106 of the present embodiment may be replaced with the interconnect of the second embodiment (i.e., the interconnect including the region extending along a plurality of directions).

The number of the connection hole (i.e., connection hole 401 or connection hole 402) in which part of the interconnect is arranged is one in the first, second and third embodiment, but the number of the connection hole (i.e., connection hole 401 or connection hole 402) may be two or more. In this case, the interconnect comprises at least one connection portion for the movable electrode, and the at least one connection portion is arranged in at least one connection hole, of the connection holes and connected to the movable electrode.

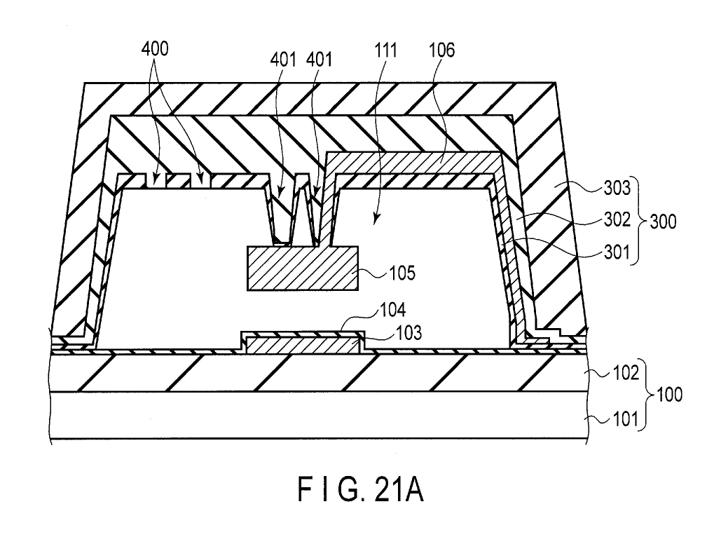

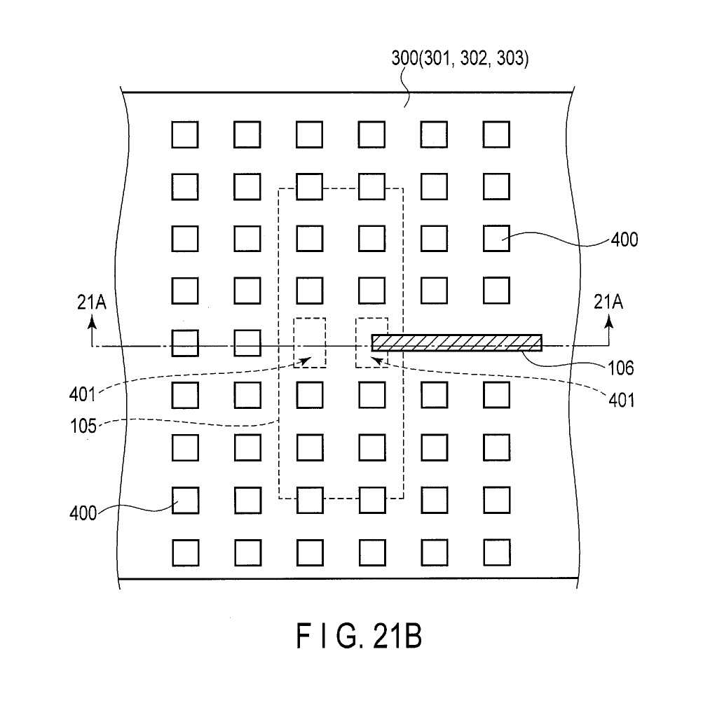

For example, the number of connection holes 401 are two, and an end portion (a connection portion) of the interconnect 106 is arranged in one of the two connection holes 401 and is connected to the movable electrode 105, as shown in FIG. 21A and FIG. 21B.

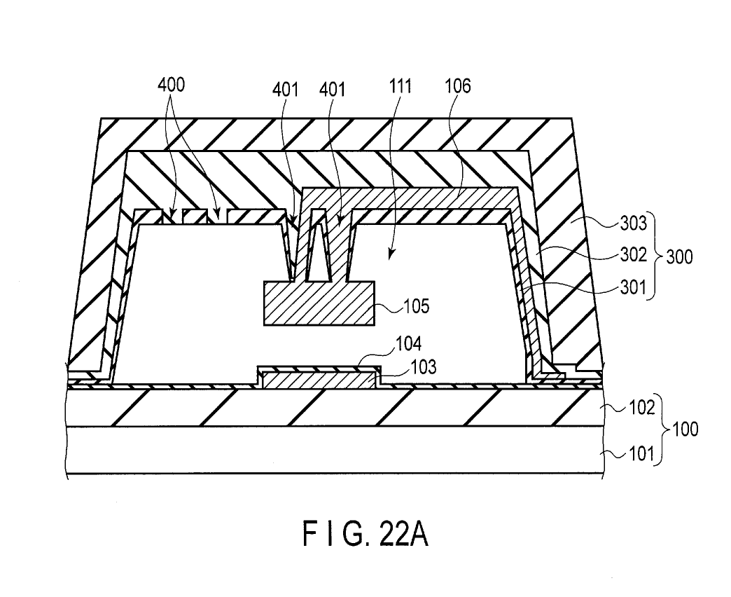

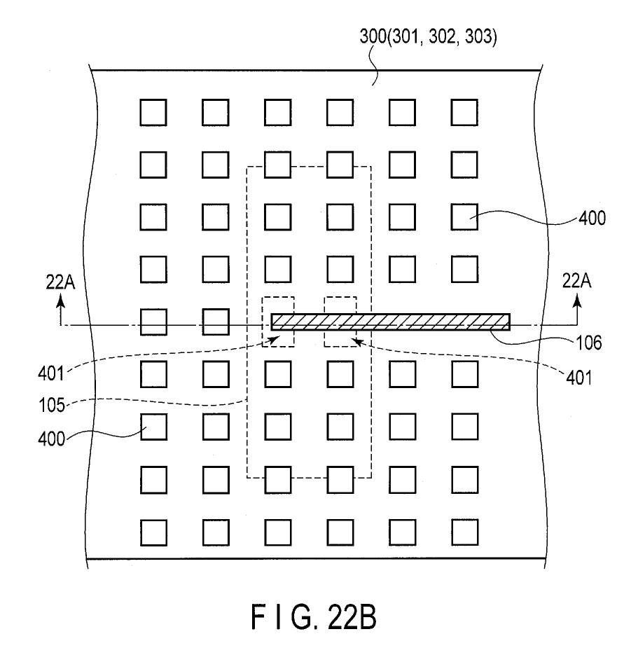

In addition, the number of connection holes 401 is two, the interconnect 106 comprises two branched end portions (a plurality of connection portions), the two branched end portions are arranged in different connection holes 401, respectively, and are connected to the movable electrode 105, as shown in FIG. 22A and FIG. 22B.

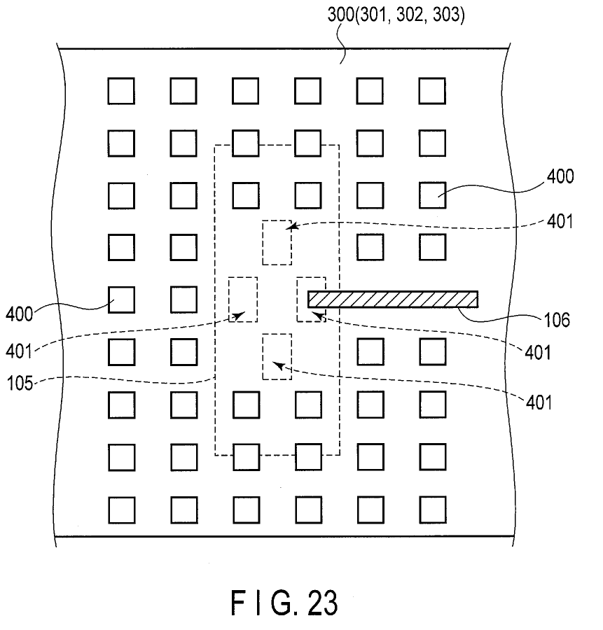

Further, the number of connection holes 401 are four, and an end portion of the interconnect 106 is arranged in one of the four connection holes 401 and is connected to the movable electrode 105, as shown in FIG. 23.

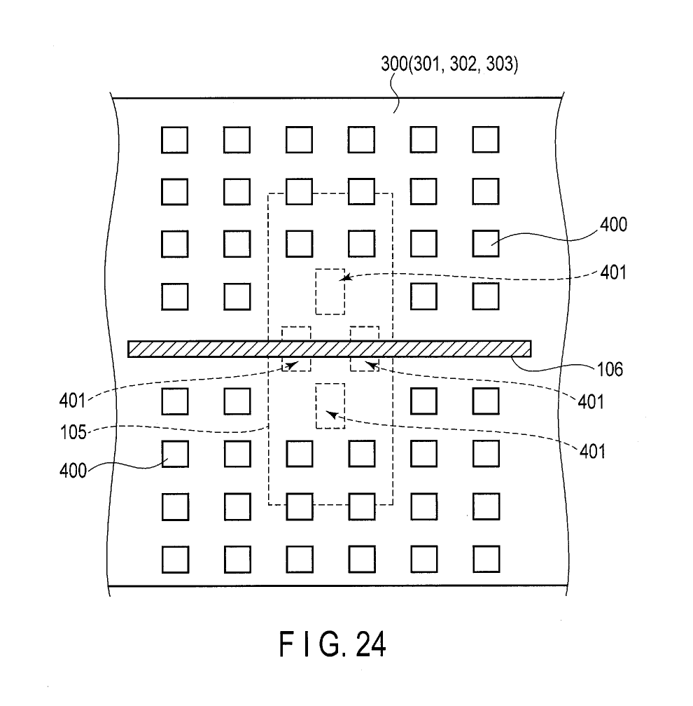

Furthermore, the number of connection holes 401 are four, the interconnect 106 comprises two connection portions at portions other than the end portion, the two connection portions are arranged in different connection holes 401, respectively, and connected to the movable electrode 105, as shown in FIG. 24. The two connection holes 401 in which the two connection portions are arranged are arranged along the longitudinal direction of the interconnect 106.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS element comprising:
a substrate;
a first electrode provided on the substrate;
a second electrode disposed above the first electrode;
a film comprising a connection hole defined by an inner wall communicating with the second electrode, the film and the substrate constituting a cavity in which the first electrode and the second electrode are contained; and
an interconnect connected to the second electrode, the interconnect comprising a portion arranged in the connection hole.

2. The device of claim 1, wherein the film comprises a first film having a plurality of through holes each defined by an inner wall facing the cavity, and a second film provided on the first film and faces the plurality of through holes.

3. The device of claim 2, wherein the first film comprises the connection hole communicating with the second electrode, and the interconnect is provided on the first film.

4. The device of claim 2, wherein the second film and the interconnect face the connection hole.

5. The device of claim 2, wherein the plurality of through holes facing the second film do not exist under the interconnect.

6. The device of claim 2, wherein the first film and the second film comprise the connection hole communicating with the second electrode, and the interconnect is provided on the second film.

7. The device of claim 6, wherein the plurality of through holes facing the second film exist under the interconnect.

8. The device of claim 2, wherein the film further comprises a third film provided on the second film.

9. The device of claim 8, wherein the third film has a lower moisture gas permeability than the second film, and the second film has a higher moisture gas permeability than the first film.

10. The device of claim 8, wherein each of the first film, the second film and the third film is an insulating film.

11. The device of claim 1, wherein a plane pattern of the interconnect includes a first region which is outside the connection hole and extends along a first direction.

12. The device of claim 11, wherein the plane pattern of the interconnect further includes a second region which is outside the connection hole and extends along a direction opposite to the first direction.

13. The device of claim 2, wherein the second film is provided to fill the plurality of through holes.

14. The device of claim 2, wherein the first electrode is a fixed electrode fixed on the substrate, and the second electrode is a movable electrode which is upwardly or downwardly movable in accordance with deformation of the film.

15. A method for manufacturing a MEMS element, the method comprising:
forming a first electrode on a substrate;
forming a first sacrifice layer covering the first electrode on the substrate
forming a second electrode on the first sacrifice layer;
forming a second sacrifice layer covering the first sacrifice layer and the second electrode;
forming a connection hole in the second sacrifice layer, the connection hole communicating with the second electrode;
forming a first film on the second sacrifice layer, the first film comprising a plurality of through holes communicating with the second sacrifice layer, and the first film covering a side surface of the connection hole to allow the second electrode to be exposed in the connection hole;
forming an interconnect connected to the second electrode on the first film, the second electrode comprising a portion arranged in the connection hole;
forming a cavity by removing the first sacrifice layer and the second sacrifice layer through the plurality of through holes, the cavity being constituted by the substrate and the first film, and the first electrode and the second electrode being contained in the cavity; and
forming a second film on the first film, the second film facing the plurality of through holes.

16. The method of claim 15, wherein the plurality of through holes facing the second film do not exist under the interconnect.

17. The device of claim 15, wherein the interconnect and the second film are formed to face the connection hole.

18. A method for manufacturing a MEMS element, the method comprising:
forming a first electrode on a substrate;
forming a first sacrifice layer covering the first electrode on the substrate;
forming a second electrode on the first sacrifice layer;
forming a second sacrifice layer covering the first sacrifice layer and the second electrode;
forming a first connection hole in the second sacrifice layer, the first connection hole communicating with the second electrode;
forming a first film on the second sacrifice layer, the first film comprising a plurality of through holes communicating with the second sacrifice layer, and the first film covering a side surface of the first connection hole to allow the second electrode to be exposed in the connection hole;
forming a cavity by removing the first sacrifice layer and the second sacrifice layer through the plurality of through holes, the cavity being constituted by the substrate and the first film, and the first electrode and the second electrode being contained in the cavity;
forming a second film on the first film, the second film facing the first connection hole and the plurality of through holes.
forming a second connection hole in the second film by processing the second film on a bottom surface of the first connection hole, the second connection hole communicating with the second electrode; and
forming an interconnect connected to the second electrode on the second film, the second electrode comprising a portion arranged in the second connection hole.

19. The method of claim 18, wherein the plurality of through holes facing the second film exist under the interconnect.

20. The method of claim 18, wherein the interconnect is formed to face the second connection hole.
